(19) United States
(12) Patent Application Publication
(10) Pub. No.: US 2025/0203993 A1
(43) Pub. Date: Jun. 19, 2025

(54) NANOSHEET FIELD EFFECT TRANSISTOR WITH CONTINUOUS SPACER

(71) Applicant: INTERNATIONAL BUSINESS MACHINES CORPORATION, ARMONK, NY (US)

(72) Inventors: Jianwei Peng, Clifton Park, NY (US); Ruilong Xie, Niskayuna, NY (US); Hiroyuki Miyazoe, White Plains, NY (US); Jun Liu, Clifton Park, NY (US)

(21) Appl. No.: 18/539,142

(22) Filed: Dec. 13, 2023

(51) Int. Cl. H01L 29/66; H01L 21/762; H01L 27/088; H01L 29/06; H01L 29/423; H01L 29/775; H01L 29/786

(52) U.S. Cl. CPC H10D 64/021; H01L 21/76224; H10D 30/43; H10D 30/6735; H10D 30/6757; H10D 62/119; H10D 84/83

(57) ABSTRACT

A semiconductor device includes a shallow trench isolation (STI), a plurality of fins over the STI, a plurality of gate regions, and a spacer layer. Each of the plurality of fins includes at least a source/drain region. Portions of the STI between the plurality of fins and portions of the STI between the plurality of gate regions are isolated by the first spacer layer.

### BACKGROUND

### Technical Field

The present disclosure generally relates to transistors, and more particularly, to spacer layer in transistors structure and methods of creation thereof.

### Description of the Related Art

By extending the gate-all-around structure idea of field-effect transistors (FETs) to a vertically stacked 3D layout, nanosheet architecture aims to sustain historical transistor density and performance scaling for possibly another decade. Nanosheet FETs were introduced to extend the scalability and performance of FETs down to the 3 nm node and beyond. They consist of thin silicon nanosheet channels stacked vertically in large numbers to maximize drive current within a small footprint. Nanosheets are formed by selectively etching alternating layers, then removing some layers, leaving dense nanosheets covered by a gate stack. The increased number of conducting channels compared to FETs offers both higher drive current and greater width control to optimize transistor characteristics.

### SUMMARY

According to an embodiment, a semiconductor device includes a shallow trench isolation (STI), a plurality of fins over the STI, a plurality of gate regions, and a spacer layer. Each of the plurality of fins includes at least a source/drain region. Portions of the STI that are located between the plurality of fins and portions of the STI that are located between the plurality of gate regions are isolated by the first spacer layer.

In some embodiments, which can be combined with the previous embodiment, portions of sidewalls of the plurality of gate regions and portions of sidewalls of the plurality of fins are isolated by a second spacer layer.

In some embodiments, which can be combined with one or more previous embodiments, the first spacer layer and the second spacer layer form a continuous layer.

In some embodiments, which can be combined with one or more previous embodiments, the first spacer layer and the second spacer layer are made of a same material.

In some embodiments, which can be combined with one or more previous embodiments, the first spacer layer and the second spacer layer are made of different materials.

In some embodiments, which can be combined with one or more previous embodiments, the semiconductor device is a nanosheet field-effect transistor (FET).

In some embodiments, which can be combined with one or more previous embodiments, the nanosheet FET includes nanosheets of alternating layers of silicon and silicon germanium.

According to an embodiment, a semiconductor device includes a shallow trench isolation (STI), a plurality of fins over the STI, a plurality of gate regions, and a spacer layer. Portions of sidewalls of the plurality of gate regions and portions of sidewalls of the plurality of fins are isolated by the first spacer layer. Each of the plurality of fins comprises at least a source/drain region.

In some embodiments, which can be combined with the previous embodiment, portions of the STI between the plurality of fins and portions of the STI between the plurality of gate regions are isolated by a second spacer layer.

In some embodiments, which can be combined with one or more previous embodiments, the first spacer layer and the second spacer layer form a continuous layer.

In some embodiments, which can be combined with one or more previous embodiments, the first spacer layer and the second spacer layer are made of a same material.

In some embodiments, which can be combined with one or more previous embodiments, the first spacer layer and the second spacer layer are made of different materials.

In some embodiments, which can be combined with one or more previous embodiments, the semiconductor device is a nanosheet field-effect transistor (FET).

In some embodiments, which can be combined with one or more previous embodiments, the nanosheet FET includes nanosheets of alternating layers of silicon and silicon germanium.

According to an embodiment, a method for forming a semiconductor device includes forming a shallow trench isolation (STI), forming a plurality of fins over the STI, forming a spacer layer, forming a plurality of gate regions, and isolating portions of the STI that are located between the plurality of fins and the plurality of gate regions by the first spacer layer. Forming each of the plurality of fins includes forming at least a source/drain region.

In some embodiments, which can be combined with the previous embodiment, the method includes isolating portions of sidewalls of the plurality of gate regions and portions of sidewalls of the plurality of fins by a second spacer layer.

In some embodiments, which can be combined with one or more previous embodiments, the method includes forming a continuous layer by connecting the first spacer layer and the second spacer layer.

In some embodiments, which can be combined with one or more previous embodiments, the first spacer layer and the second spacer layer are made of a same material.

In some embodiments, which can be combined with one or more previous embodiments, the first spacer layer and the second spacer layer are made of different materials.

In some embodiments, which can be combined with one or more previous embodiments, the method includes forming nanosheets of alternating layers of silicon and silicon germanium.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIGS. 1A-1C illustrate different cross-section views of a semiconductor device, in accordance with some embodiments.

FIG. 1D depicts the side-view sections from which the semiconductor device is illustrated.

FIGS. 2A-2C illustrate a semiconductor device, in accordance with some embodiments.

FIGS. 3A-3C illustrate a semiconductor device after the deposition of self-aligned substrate isolation (SASI), in accordance with some embodiments.

FIGS. 4A-4C illustrate a semiconductor device after the deposition of organic planarization layer (OPL), in accordance with some embodiments.

FIGS. 5A-5C illustrate a semiconductor device after etching the mask layer, in accordance with some embodiments.

FIGS. 6A-6C illustrate a semiconductor device after etching the first spacer, in accordance with some embodiments.

FIGS. 7A-7C illustrate a semiconductor device after stripping the organic planarization layer (OPL), in accordance with some embodiments.

FIGS. 8A-8C illustrate a semiconductor device after the formation of the source/drain region, in accordance with some embodiments.

FIGS. 9A-9C illustrate a semiconductor device after the deposition of self-aligned substrate isolation (SASI), in accordance with some embodiments.

FIGS. 10A-10C illustrate a semiconductor device after etching the first spacer, in accordance with some embodiments.

FIGS. 11A-11C illustrate a semiconductor device after formation of the second spacer, in accordance with some embodiments.

FIGS. 12A-12C illustrate a semiconductor device after deposition of the organic planarization layer (OPL), in accordance with some embodiments.

FIGS. 13A-13C illustrate a semiconductor device after etching the second spacer, in accordance with some embodiments.

FIGS. 14A-14C illustrate a semiconductor device after stripping the organic planarization layer (OPL), in accordance with some embodiments.

FIGS. 15A-15C illustrate a semiconductor device after formation of the source/drain regions, in accordance with some embodiments.

FIG. 16 illustrates a block diagram of a method for forming the semiconductor device, in accordance with some embodiments.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the embodiments is not limiting. In particular, elements of the embodiments described hereinafter may be combined with elements of different embodiments.

As used herein, certain terms are used indicating what may be considered an idealized behavior, such as, for example, “lossless,” “superconductor,” or “superconducting,” which are intended to cover functionality that may not be exactly ideal but is within acceptable margins for a given application. For example, a certain level of loss or tolerance may be acceptable such that the resulting materials and structures may still be referred to by these “idealized” terms.

The concepts herein relate to nanosheet field-effect transistor (FET), which are fundamental electronic devices that have revolutionized the field of electronics and how various elements of the transistors are electrically connected. Typically, the shallow trench isolation (STI) regions around the nanosheet FET structures are recessed too deeply after the gate electrode and spacer formation steps. This excessive STI recess creates topology that increases the risk of yield and reliability failures later in the process flow. Specifically, the additional 150-200 nm of STI oxide removed forms significant trenches around the narrow fins. Subsequent processes involve aggressive poly-silicon pull and sacrificial nanosheet release etches using hot chemicals selective to silicon oxide. However, these etchant chemicals can leak through tiny residual openings at the bottom corners of the spacers along the fin X2 cut regions. This allows the chemicals to reach the underlying source/drain and channel layers. The leaked chemicals will then laterally etch away the ends of the fins and source/drain nanoribbon features. The combined lateral source/drain etching causes large holes up to 80×100 nm behind the spacer foot on the STI surface. This leads to both yield fallout and device failures later from high leakage and poor contacts.

To tackle the above-mentioned issues, disclosed is a semiconductor device with improved STI etch depth control to minimize topology, along with optimized spacer deposition quality to properly seal fins, to eliminate the chemical leakage failure mechanism. To that end, in one aspect, the disclosed semiconductor device utilizes a continuous spacer layer from gate sidewalls to the STI to improve the gate-source/drain isolation in nanosheet FETs.

Accordingly, the teachings herein provide methods and systems of semiconductor device formation with continuous spacer layer from the gate sidewalls to the STI. The techniques described herein may be implemented in a number of ways. Example implementations are provided below with reference to the following figures.

Example Semiconductor Device with Spacer Layer Structure

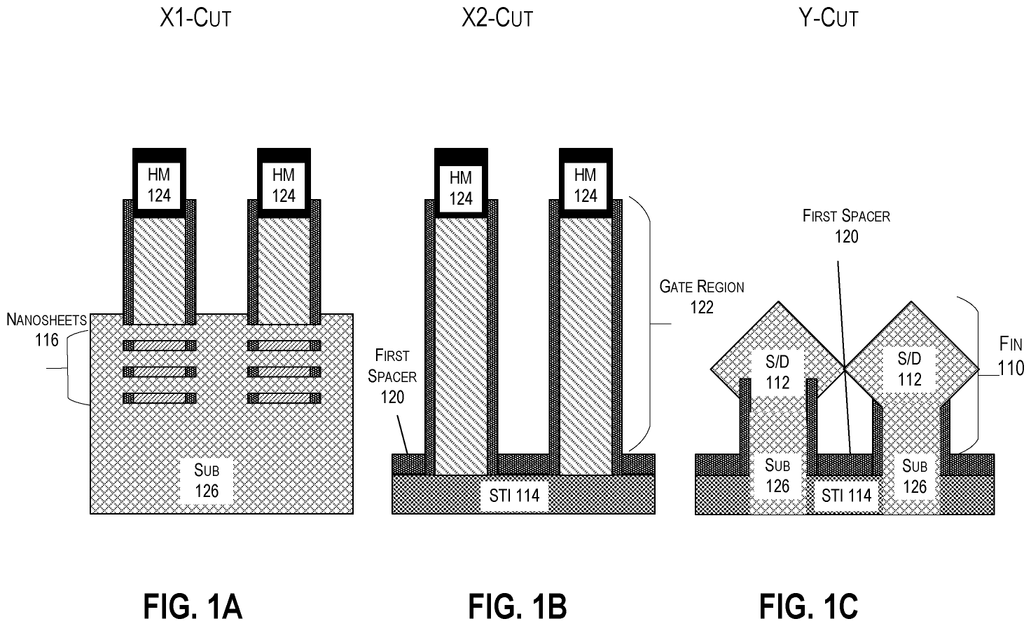

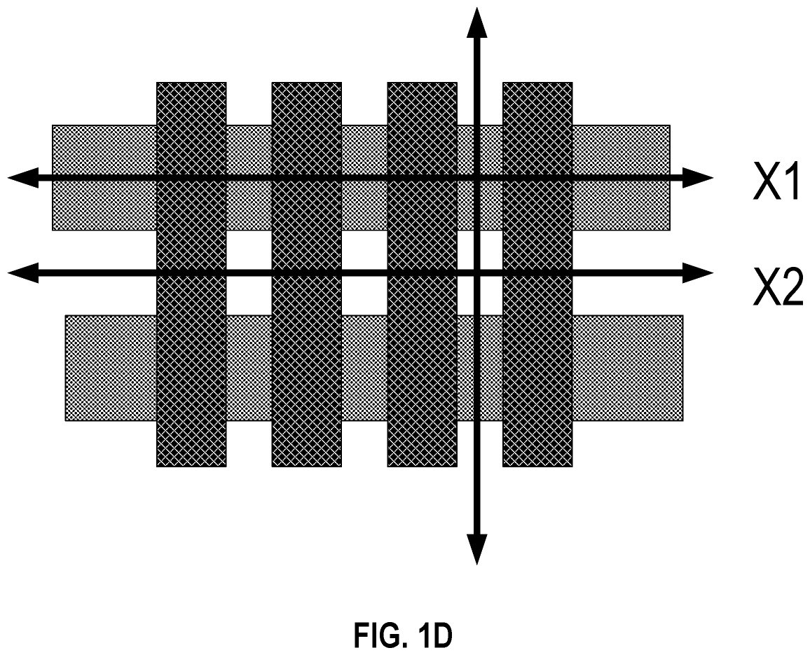

Reference now is made to FIGS. 1A-1C, which are simplified cross-section views of a semiconductor device, consistent with an illustrative embodiment. FIG. 1D depicts a top view of the semiconductor device. For example, FIG. 1A, and other figures denoted by A, illustrate an X1 section of the semiconductor device, FIG. 1B, and other figures denoted by B, illustrate a X2 section of the semiconductor device and FIG. 1C, and other figures denoted by C, illustrate a Y section of the semiconductor device with reference to FIG. 1D.

The disclosed semiconductor device can include a plurality of fins 110, a source/drain region 112, a shallow trench isolation, STI, 114, a plurality of nanosheets 116, a first spacer 120, a plurality of gate regions 122, a hard mask, HM, 124, and a substrate 126.

Each of the plurality of fins 110 can include at least one source/drain region, e.g., the source/drain region 112. Generally, the source/drain region 112 are salient components that play relevant roles in the semiconductor device's operation. In various embodiments, the plurality of source/drain regions are regions within the semiconductor material, where the current flows in and out of the semiconductor device. The source region is the region through which the majority of charge carriers (e.g., electrons or holes) enter the channel of the semiconductor device and is responsible for providing the current that flows through the semiconductor device. The source region is typically doped to have an excess of charge carriers, creating a region with high carrier concentration. This abundance of carriers allows for the efficient injection of electrons or holes into the channel when a voltage is applied.

The drain region, on the other hand, is the region where the majority of charge carriers exit the channel. The drain region receives the current from the channel and carries the charge away from the transistor. Similar to the source, the drain region is also doped to have a high carrier concentration. The doping profile in the drain region ensures that carriers can easily flow out of the channel and into the drain region. In some embodiments, one source/drain region is located on a first transistor, and another source/drain region is located on a second transistor. In such embodiments, the first transistor can be stacked on top of the second transistor to form the semiconductor device.

STI 114 is employed to electrically isolate adjacent components and transistors and other active devices on the semiconductor device. STI's function can be to prevent electrical interference and the unintended flow of electrons or holes between neighboring components, which can ensure proper operation of integrated circuits. STI 114 reduces the parasitic capacitance between adjacent devices, and avoids the bird's beak effect, where the oxide encroaches under the active regions, potentially affecting transistor characteristics.

The plurality of nanosheets 116 can include three-dimensional structures in the gate metal, which are extended from a source region towards a drain region. Each nanosheet can include one or more layers.

In some embodiments, the first spacer 120 is formed over the portions of the STI that are located between the plurality of gate regions 122. In such embodiments, the first spacer 120 can act as an insulating layer between the plurality of gate regions 122 and STI 114. In some embodiments, the first spacer 120 is formed over the portions of the STI that are located between the plurality of fins 110. In such embodiments, the first spacer 120 can act as an insulating layer between the plurality of fins 110 and STI 114. That is, the first spacer 120 can help prevent current leakage or short circuits between the plurality of gate regions 122 and the plurality of fins 110. Such isolation can help maintain the integrity of the semiconductor device's electrical operation and prevent unintended current flow that could negatively impact the performance of the semiconductor device and reliability. In some embodiments, the first spacer 120 is formed over the sidewalls of the plurality of gate regions 122 and the sidewalls of the plurality of fins 110.

In some embodiments, the first spacer 120 formed over the portions of the STI that are located between the plurality of gate regions 122 and the first spacer 120 formed over the sidewalls of the plurality of gate regions 122 can form a continuous spacer layer. Alternatively, in some embodiments, the first spacer 120 formed over the portions of the STI that are located between the plurality of gate regions 122 and the first spacer 120 formed over the sidewalls of the plurality of gate regions 122 do not attach together and, as such, do not form a continuous spacer layer.

In some embodiments, the first spacer 120 formed over the portions of the STI that are located between the plurality of fins 110 and the first spacer 120 formed over the sidewalls of the plurality of fins 110 can form a continuous spacer layer. Alternatively, in some embodiments, the first spacer 120 formed over the portions of the STI that are located between the plurality of fins 110 and the first spacer 120 formed over the sidewalls of the plurality of fins 110 do not attach together and, as such, do not form a continuous spacer layer.

In further embodiments, the first spacer 120 can be utilized to modulate the overlapping capacitance between the plurality of gate regions 122 and the plurality of fins 110. Overlapping capacitance can affect the semiconductor device's electrical characteristics, such as threshold voltage and switching behavior. Thus, by adjusting the thickness and material properties of the first spacer 120, the overlapping capacitance can be optimized, which can allow for better control and modulation of the semiconductor device's behavior.

In several embodiments, the first spacer 120 can help mitigate the short-channel effects by physically separating the plurality of gate regions 122 from the plurality of fins 110. To that end, the first spacer 120 can create a barrier that restricts the extension of the electric field into the channel region, reducing the impact of drain-induced barrier lowering and subthreshold leakage. This mitigation can improve the semiconductor device's performance, reduce power consumption, and enhance overall device reliability.

In various embodiments, the plurality of gate regions 122 serve as control elements that regulate the flow of current through the semiconductor device. The plurality of gate regions 122 can be composed of a conductive material. The plurality of gate regions 122 can control the flow of electric current between the source and drain regions. In some embodiments, by applying a voltage to the gate, the channel region's conductivity is modulated, allowing the semiconductor device to either allow or block the flow of current, which in turn enables the semiconductor device to act as electronic switches or amplifiers. The gate voltage can determine whether the semiconductor device is in an “on” or “off” state. When the gate voltage is below a certain threshold, the semiconductor device is in the “off” state, and the current flow between the source and drain is effectively blocked. On the other hand, when the gate voltage exceeds the threshold, the semiconductor device enters the “on” state, allowing current to flow through the channel region. In addition to acting as a switch, modulating the gate voltage can enable the plurality of gate regions 122 to control the current flowing through the channel region, resulting in amplified output signals.

In an embodiment, the plurality of gate regions 122 can enable the implementation of Boolean logic operations, such as AND, OR, and NOT, by controlling the flow of current based on the input voltages. Multiple semiconductor devices can be interconnected to form complex logic circuits, enabling the execution of various computational tasks in digital systems. In some embodiments, the plurality of gate regions 122, along with other semiconductor device components, can facilitate the miniaturization and integration of electronic circuits. The ability to control the channel region's conductivity through the gate voltage allows for compact and highly efficient circuit designs.

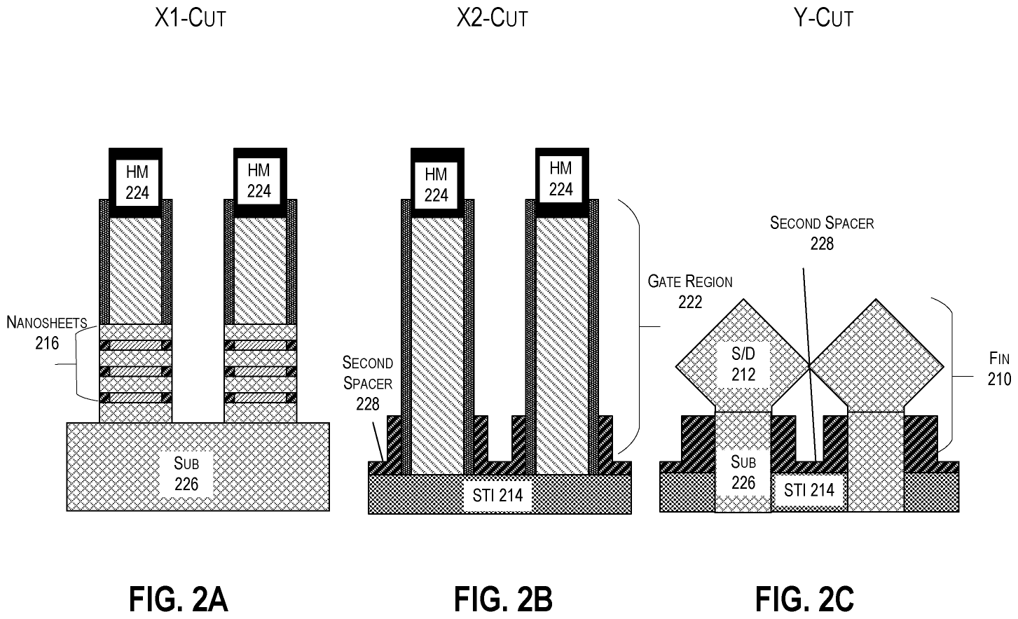

Reference now is made to FIGS. 2A-2C, which are simplified cross-section views of a semiconductor device, consistent with an illustrative embodiment. The semiconductor device depicted in FIGS. 2A-2C can include a plurality of fins 210, one or more source/drain regions 212, a shallow trench isolation, STI, 214, a plurality of nanosheets 216, a plurality of gate regions 222, a hard mask, HM, 224, a substrate 226, and a second spacer 228.

Each of the plurality of fins 210 can include at least one source/drain region, e.g., the source/drain region 212. Generally, the source/drain region 212 are salient components that play relevant roles in the semiconductor device's operation. In various embodiments, the plurality of source/drain regions are regions within the semiconductor material, where the current flows in and out of the semiconductor device. The source region is the region through which the majority of charge carriers (e.g., electrons or holes) enter the channel of the semiconductor device and is responsible for providing the current that flows through the semiconductor device. The source region is typically doped to have an excess of charge carriers, creating a region with high carrier concentration. This abundance of carriers allows for the efficient injection of electrons or holes into the channel when a voltage is applied.

The drain region, on the other hand, is the region where the majority of charge carriers exit the channel. The drain region receives the current from the channel and carries the charge away from the transistor. Similar to the source, the drain region is also doped to have a high carrier concentration. The doping profile in the drain region ensures that carriers can easily flow out of the channel and into the drain region. In some embodiments, one source/drain region is located on a first transistor, and another source/drain region is located on a second transistor. In such embodiments, the first transistor can be stacked on top of the second transistor to form the semiconductor device.

STI 214 is employed to electrically isolate adjacent components and transistors and other active devices on the semiconductor device. STI's function can be to prevent electrical interference and the unintended flow of electrons or holes between neighboring components, which can ensure proper operation of integrated circuits. STI 214 reduces the parasitic capacitance between adjacent devices, and avoids the bird's beak effect, where the oxide encroaches under the active regions, potentially affecting transistor characteristics.

The plurality of nanosheets 216 can include three-dimensional structures in the gate metal, which are extended from a source region towards a drain region. Each nanosheet can include one or more layers.

In various embodiments, the plurality of gate regions 222 serve as control elements that regulate the flow of current through the semiconductor device. The plurality of gate regions 222 can be composed of a conductive material. The plurality of gate regions 222 can control the flow of electric current between the source and drain regions. In some embodiments, by applying a voltage to the gate, the channel region's conductivity is modulated, allowing the semiconductor device to either allow or block the flow of current, which in turn enables the semiconductor device to act as electronic switches or amplifiers. The gate voltage can determine whether the semiconductor device is in an “on” or “off” state. When the gate voltage is below a certain threshold, the semiconductor device is in the “off” state, and the current flow between the source and drain is effectively blocked. On the other hand, when the gate voltage exceeds the threshold, the semiconductor device enters the “on” state, allowing current to flow through the channel region. In addition to acting as a switch, modulating the gate voltage can enable the plurality of gate regions 222 to control the current flowing through the channel region, resulting in amplified output signals.

In an embodiment, the plurality of gate regions 222 can enable the implementation of Boolean logic operations, such as AND, OR, and NOT, by controlling the flow of current based on the input voltages. Multiple semiconductor devices can be interconnected to form complex logic circuits, enabling the execution of various computational tasks in digital systems. In some embodiments, the plurality of gate regions 222, along with other semiconductor device components, can facilitate the miniaturization and integration of electronic circuits. The ability to control the channel region's conductivity through the gate voltage allows for compact and highly efficient circuit designs.

In some embodiments, the second spacer 228 is formed over the portions of the STI that are located between the plurality of gate regions 222. In such embodiments, the second spacer 228 can act as an insulating layer between the plurality of gate regions 222 and STI 214. In some embodiments, the second spacer 228 is formed over the portions of the STI that are located between the plurality of fins 210. In such embodiments, the second spacer 228 can act as an insulating layer between the plurality of fins 210 and STI 214. That is, the second spacer 228 can help prevent current leakage or short circuits between the plurality of gate regions 222 and the plurality of fins 210. Such isolation can help maintain the integrity of the semiconductor device's electrical operation and prevent unintended current flow that could negatively impact the performance of the semiconductor device and reliability.

In further embodiments, the second spacer 228 can be utilized to modulate the overlapping capacitance between the plurality of gate regions 222 and the plurality of fins 210. Overlapping capacitance can affect the semiconductor device's electrical characteristics, such as threshold voltage and switching behavior. Thus, by adjusting the thickness and material properties of the second spacer 228, the overlapping capacitance can be optimized, which can allow for better control and modulation of the semiconductor device's behavior.

In several embodiments, the second spacer 228 can help mitigate the short-channel effects by physically separating the plurality of gate regions 222 from the plurality of fins 210. To that end, the second spacer 228 can create a barrier that restricts the extension of the electric field into the channel region, reducing the impact of drain-induced barrier lowering and subthreshold leakage. This mitigation can improve the semiconductor device's performance, reduce power consumption, and enhance overall device reliability.

In some embodiments, the second spacer 228 can cover portions of the sidewalls of the plurality of gate regions 222. In some embodiments, where the semiconductor device includes a self-aligned substrate isolation, SASI, over the substrate, the height of the second spacer 228 is substantially equal to the sum of the height of the substrate 226 and the SASI. As a result, the plurality of nanosheets 216 remain exposed and uncovered by the second spacer 228.

In some embodiments, the second spacer 228 formed over the portions of the STI that are located between the plurality of gate regions 222 and the second spacer 228 formed over the sidewalls of the plurality of gate regions 222 can form a continuous spacer layer. Alternatively, in some embodiments, the second spacer 228 formed over the portions of the STI that are located between the plurality of gate regions 222 and the second spacer 228 formed over the sidewalls of the plurality of gate regions 222 do not attach together and, as such, do not form a continuous spacer layer.

Example Processes for Semiconductor Device with Spacer Layer Structures

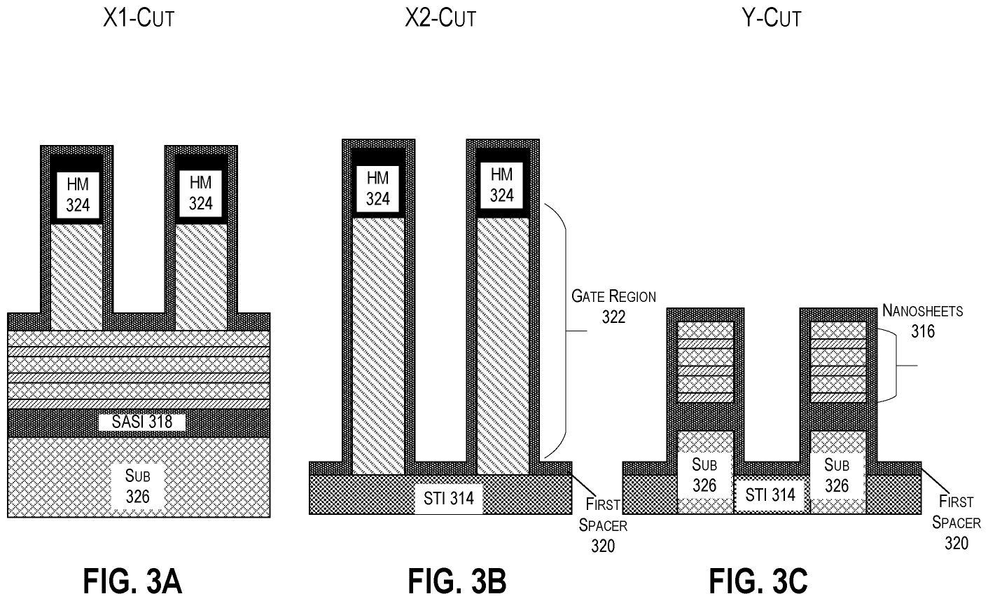

With the foregoing description of an example semiconductor device, it may be helpful to discuss an example process of manufacturing the same. To that end, FIGS. 3-8 illustrate various steps in the manufacture of a semiconductor device, consistent with illustrative embodiments. As noted above, figures denoted by A, B, and C illustrate an act of fabrication of the semiconductor device from a different point of view. It is also worth mentioning that the semiconductor depicted in FIGS. 1A-1C can be the same as the semiconductor depicted in FIGS. 3-8.

Referring to FIGS. 3A-3C now, a semiconductor device after SASI deposition, in accordance with some embodiments. The semiconductor device can include STI, 314, a plurality of nanosheets 316, a self-aligned substrate isolation, SASI, 318, a gate region 322, a hard mask, HM, 324, and a substrate 326.

In the illustrative example depicted in FIGS. 3A-3C, the semiconductor device is depicted as being on silicon as the substrate 326, while it will be understood that other types as substrates may be used as well, including, without limitation, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs), and quaternary (four elements, e.g., aluminum gallium indium phosphide (AlInGaP)) alloys.

In various embodiments, the substrates 326 may include any suitable material or combination of materials, such as doped or undoped silicon, glass, dielectrics, etc. For example, the substrate may include a silicon-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating film on top.

The process of fabricating STI 314 begins with the creation of shallow trenches on the silicon wafer's surface. These trenches are typically very narrow and shallow in depth, which is why they are referred to as shallow trenches. After trench formation, the trenches are filled with an insulating dielectric material, such as silicon dioxide (SiO2) or a high-density plasma-enhanced chemical vapor deposition (HDPE-CVD) oxide. This dielectric material serves as an electrical barrier between adjacent active components. In some embodiments, chemical mechanical polishing (CMP) is employed to remove excess material, leaving a flat and planarized surface. In other words, CMP ensures that the surface of the wafer is flat, facilitating subsequent photolithography and layer deposition steps.

In some embodiments, the plurality of nanosheets 316 can be formed by alternating layers of Si and SiGe (not shown), in which sidewalls of the SiGe layers are indented and covered by the inner spacer. The SiGe layers can subsequently be removed and replaced with gate region materials.

SASI 318 can electrically isolate individual components in the semiconductor device, and provide electrical isolation between each of the FETs in a stacked FET. That is, SASI 318 can ensure that the operation of one transistor does not interfere with the operation of the others. By using a dielectric layer, which is an insulating layer that does not conduct electricity, the SASI 318 effectively prevents electrical crosstalk between the transistors and allows each one to operate independently. Further, by electrically isolating each transistor from the other, SASI 318 can reduce the potential for crosstalk, which is the unwanted transfer of signals between circuit elements, thereby improving the overall performance of the semiconductor device.

By isolating each transistor, SASI 318 helps to prevent the failure of one transistor from affecting the others. This can improve the overall reliability of the device. Additionally, the SASI 318 allows for more flexibility in device design, as it allows each transistor in the stack to be accessed and controlled independently. This can be beneficial in a variety of applications where specific transistors may need to be activated or deactivated based on certain conditions. In some embodiments, SASI 318 can help decrease the parasitic capacitance associated with the transistor, which can lead to faster switching times and improved performance.

The first spacer 320 can be formed by deposition techniques. Alternatively, the first spacer 224 can be formed by etching or selectively epitaxially growing the first spacer 320 over the sidewalls of the gate regions 322. In various embodiments, the first spacer 320 can include SiGe. The first spacer 320 can be made of the same material as the SASI 318.

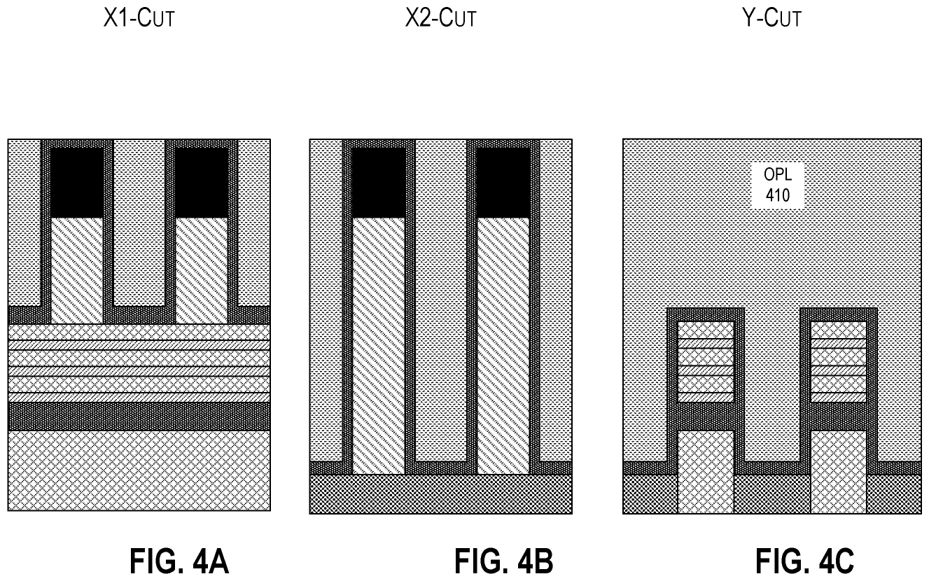

FIGS. 4A-4C illustrate a semiconductor device after OPL deposition, in accordance with some embodiments. In some embodiments, an organic planarization layer, OPL, 410 is formed over the semiconductor device. The OPL 410 can include a photo-sensitive organic polymer having a light-sensitive material that, when exposed to electromagnetic radiation, is chemically altered and thus configured to be removed using a developing solvent. For example, in some embodiments, the photo-sensitive organic polymer can be polyacrylate resin, epoxy resin, phenol resin, polyamide resin, polyimide resin, unsaturated polyester resin, polyphenylene ether resin, polyphenylene sulfide resin, or benzo-cyclobutene (BCB). In some embodiments, the OPL 410 can include any organic polymer and a photoactive compound having a molecular structure that can attach to the molecular structure of the organic polymer. In some embodiments, the OPL 410 material is selected to be compatible with an overlying antireflective coating (not shown) and/or an overlying photoresist (not shown). In some embodiments, the OPL 410 can be applied using spin coating technology, although other techniques are within the contemplated scope of the present disclosure. In some embodiments, amorphous silicon, aSi, can be deposited. Alternatively, in some embodiments, an oxide is deposited followed by a CMP to planarize the semiconductor device.

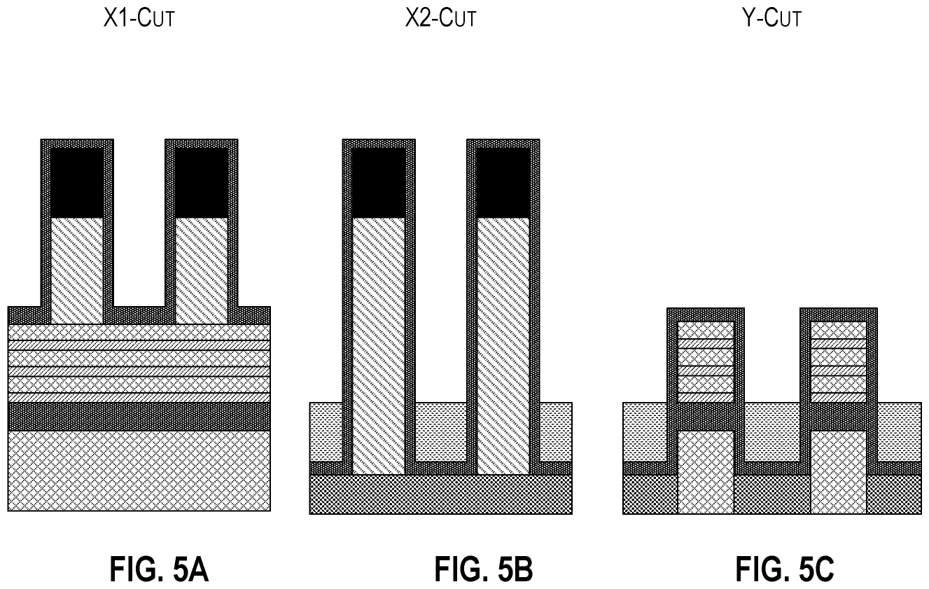

FIGS. 5A-5C illustrate a semiconductor device after etching the mask layer, in accordance with some embodiments. In some embodiments, portions of the OPL are etched. The etching is stopped once the sidewalls of the plurality of nanosheets are exposed. As such, SASI and the first spacer remain covered by the OPL.

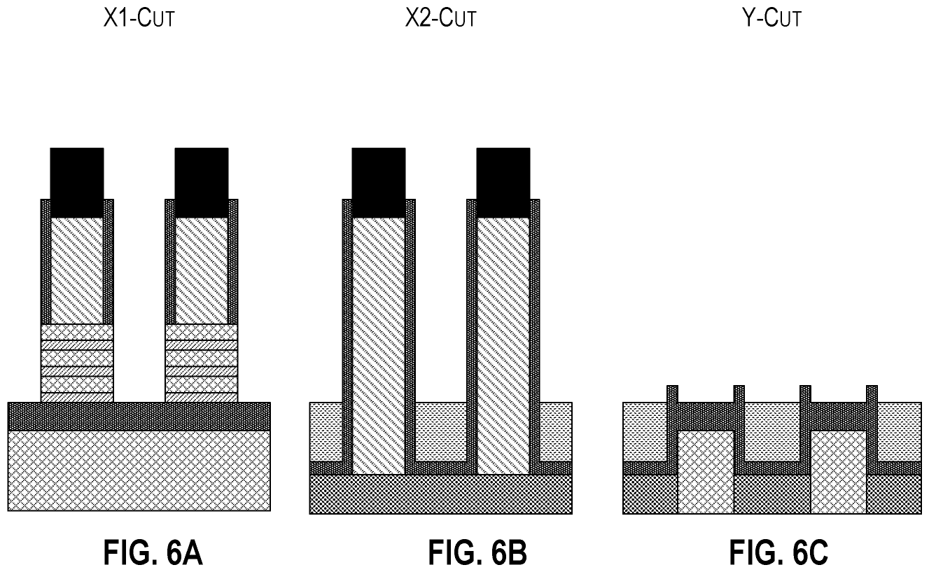

FIGS. 6A-6C illustrate a semiconductor device after etching the first spacer, in accordance with some embodiments. In some embodiments, portions of the first spacer are removed and the plurality of fins are recessed. The portions of the first spacer can be removed by a reactive ion etching (RIE) technique. Generally, RIE is a dry etching process used in semiconductor device fabrication to remove materials from the surface of a substrate selectively. In some embodiments, RIE can involve the use of reactive ions and plasma to react with and remove specific materials chemically. In an embodiment, the RIE process begins by placing the semiconductor device inside a vacuum chamber. The chamber is then evacuated to create a low-pressure environment. Reactive gases, which can include a combination of a chemically reactive gas and an inert gas, are introduced into the chamber. The chemically reactive gas, such as fluorine-based gases (e.g., CF4, SF6) or chlorine-based gases (e.g., Cl2), can react with the material to be etched, i.e., the second substrate, Si, while the inert gas, e.g., argon, can help to control the ion bombardment.

In some embodiments, Radiofrequency or microwave power is applied to create a plasma within the chamber. In such embodiments, power excites the gas molecules, causing them to ionize and form a plasma of reactive ions and electrons. The plasma can include reactive ions that chemically react with the silicon. The reactive ions bombard the substrate surface, break chemical bonds and remove silicon. In various embodiments, the RIE process can be selective, meaning it can mainly affect the target material, i.e., silicon, while leaving other materials, such as masking layers or underlying layers, relatively unaffected.

In some embodiments, to achieve selective etching, an etch mask can be applied on the substrate surface prior to the RIE process. The etch mask protects certain regions from etching, allowing the reactive ions to remove the exposed material selectively. The etching process can be controlled to achieve specific etch profiles, such as vertical sidewalls or tapered structures. Parameters such as gas composition, pressure, power, and process duration are adjusted to achieve the desired etch characteristics. In some embodiments, endpoint detection techniques, such as optical emission spectroscopy or laser interferometry, can be used to determine when the etching process has reached a desired endpoint. This ensures accurate control of the etch depth and prevents over-etching. After the etching process is completed, the substrate can be cleaned to remove any residue or by-products from the etching. Cleaning can involve rinsing with solvents or plasma cleaning to ensure the substrate's surface is free from contaminants. Once the RIE process is performed, the plurality of nanosheets are recessed. The etching process stops at the SASI level in X1 section and OPL in X2 section and Y section.

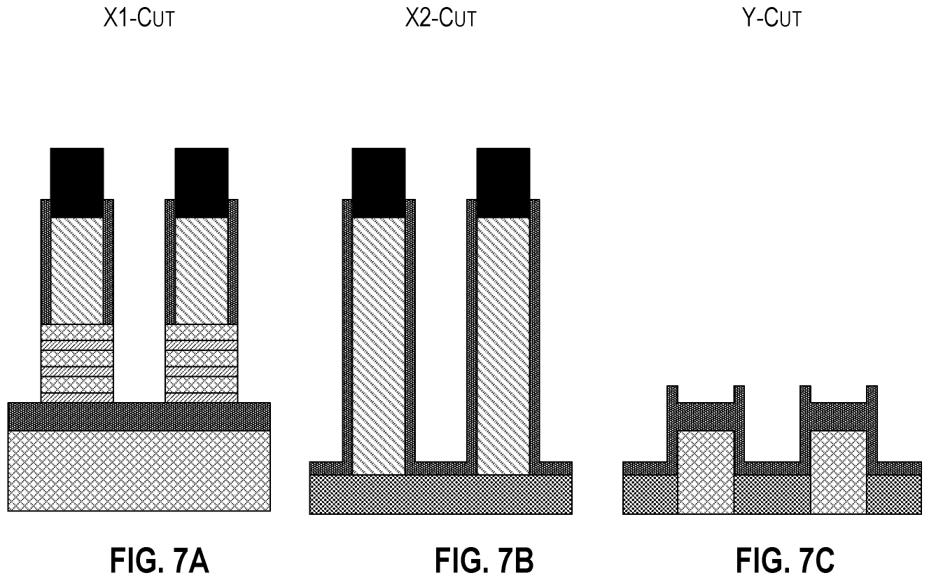

FIGS. 7A-7C illustrate a semiconductor device after stripping the OPL, in accordance with some embodiments. In some embodiments, the remaining OPL is stripped and SASI and the first spacer are exposed.

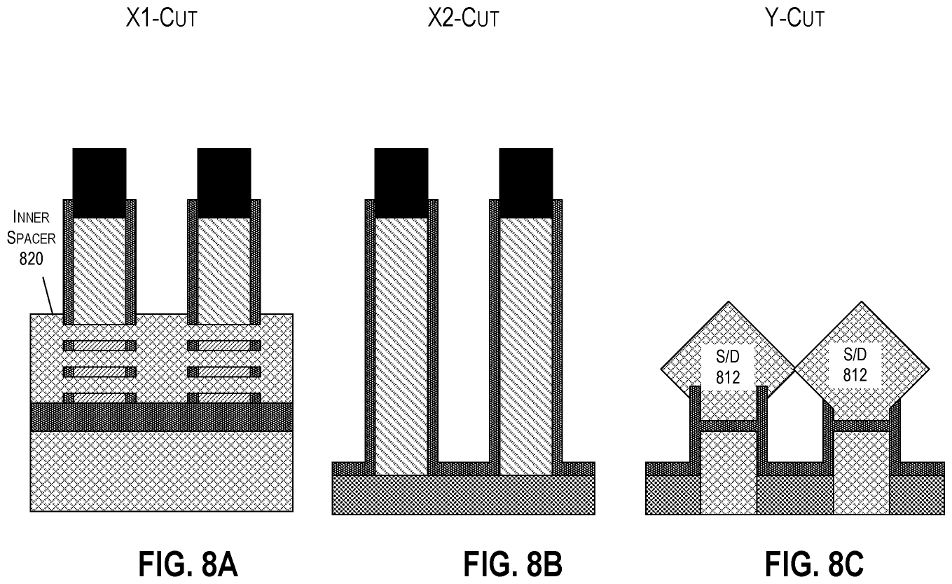

FIGS. 8A-8C illustrate a semiconductor device after the formation of the source/drain regions, in accordance with some embodiments. In some embodiments, the source/drain regions 812 are formed. The source/drain regions 812 can be epitaxially grown. In some embodiments, the inner spacer 820 is formed over the plurality of nanosheets. The inner spacer 820 can act as an insulating layer between the gate regions and the source/drain regions 812. In various embodiments, the inner spacer 820 can be made of the same material as the first spacer.

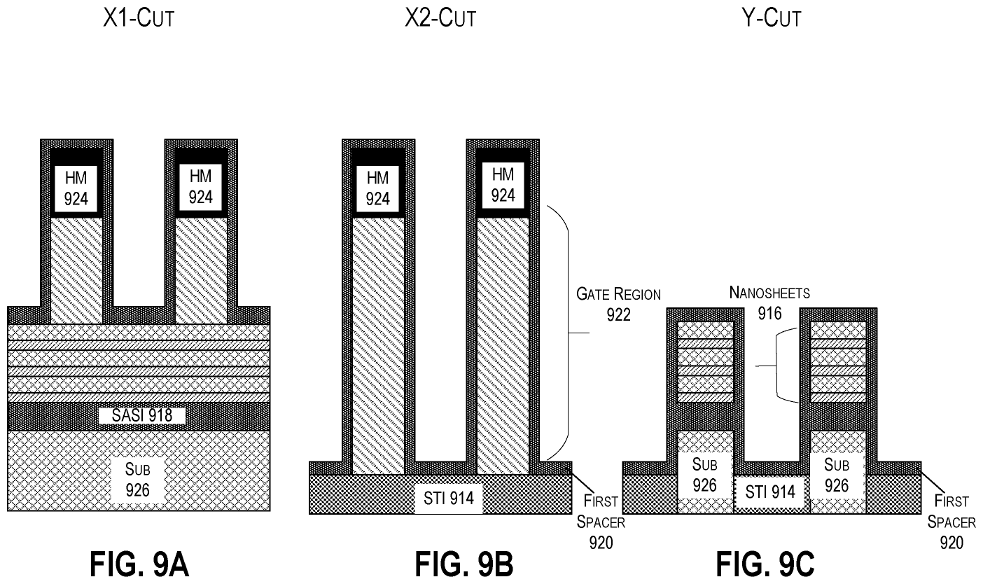

FIGS. 9-15 illustrate various steps in the manufacture of a semiconductor device, consistent with illustrative embodiments. It is also worth mentioning that the semiconductor depicted in FIGS. 2A-2C can be the same as the semiconductor depicted in FIGS. 9-15.

Referring to FIGS. 9A-9C now, a semiconductor device after SASI deposition, in accordance with some embodiments. The semiconductor device can include STI, 914, a plurality of nanosheets 916, SASI 918, a gate region 922, a hard mask, HM, 924, and a substrate 926.

In the illustrative example depicted in FIGS. 9A-9C, the semiconductor device is depicted as being on silicon as the substrate 926, while it will be understood that other types as substrates may be used as well, including, without limitation, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs), and quaternary (four elements, e.g., aluminum gallium indium phosphide (AlInGaP)) alloys.

In various embodiments, the substrates 926 may include any suitable material or combination of materials, such as doped or undoped silicon, glass, dielectrics, etc. For example, the substrate may include a silicon-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating film on top.

The process of fabricating STI 914 begins with the creation of shallow trenches on the silicon wafer's surface. These trenches are typically very narrow and shallow in depth, which is why they are referred to as shallow trenches. After trench formation, the trenches are filled with an insulating dielectric material, such as silicon dioxide (SiO2) or a high-density plasma-enhanced chemical vapor deposition (HDPE-CVD) oxide. This dielectric material serves as an electrical barrier between adjacent active components. In some embodiments, chemical mechanical polishing (CMP) is employed to remove excess material, leaving a flat and planarized surface. In other words, CMP ensures that the surface of the wafer is flat, facilitating subsequent photolithography and layer deposition steps.

In some embodiments, the plurality of nanosheets 916 can be formed by alternating layers of Si and SiGe (not shown), in which sidewalls of the SiGe layers are indented and covered by the inner spacer. The SiGe layers can subsequently be removed and replaced with gate region materials.

The first spacer 920 can be formed by deposition techniques. Alternatively, the first spacer 924 can be formed by etching or selectively epitaxially growing the first spacer 920 over the sidewalls of the gate regions 922. In various embodiments, the first spacer 920 can include SiGe.

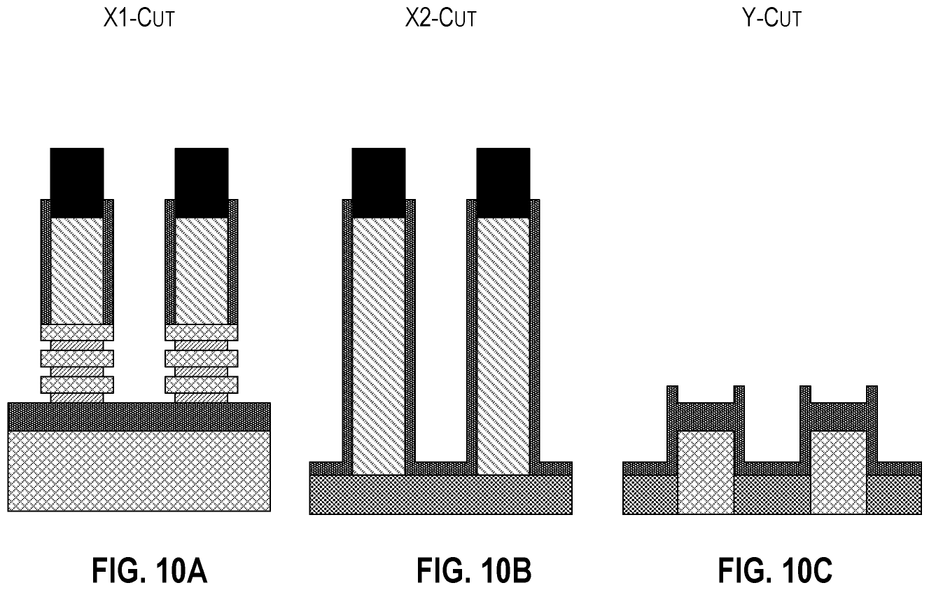

FIGS. 10A-10C illustrate a semiconductor device after etching the first spacer, in accordance with some embodiments. In some embodiments, portions of the first spacer are removed and the plurality of fins are recessed. The portions of the first spacer can be removed by RIE technique. Once the RIE process is performed, the plurality of nanosheets are recessed. The etching process stops at the SASI level in X1 section and STI in X2 section and Y section. In some embodiments, the inner spacer layer over the plurality of nanosheets is indented.

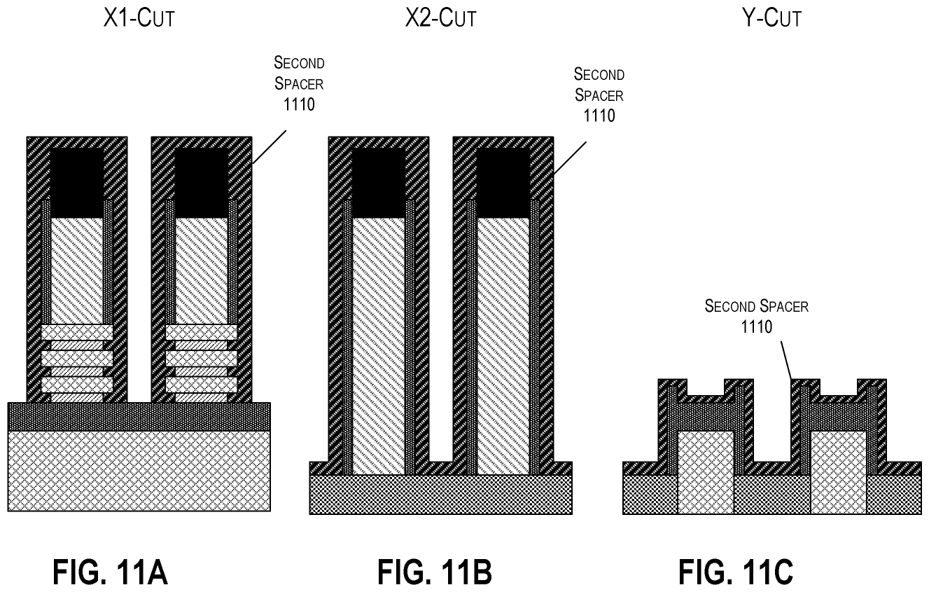

FIGS. 11A-11C illustrate a semiconductor device after the formation of the second spacer, in accordance with some embodiments. In some embodiments, the second spacer 1110 is formed over the semiconductor device. The second spacer 1110 can cover the plurality of fins and the plurality of gate regions. The first spacer 320 can be made of the same material as the SASI 318.

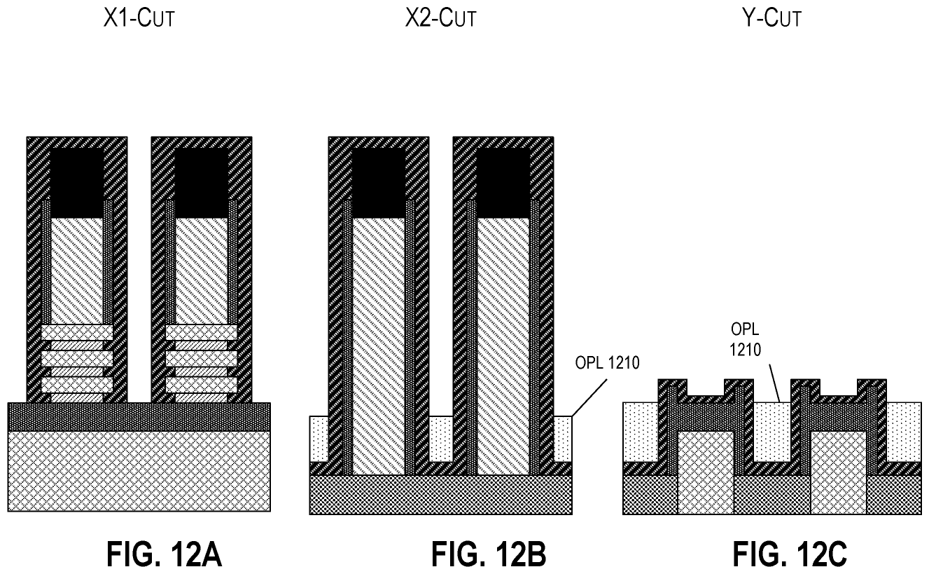

FIGS. 12A-12C illustrate a semiconductor device after OPL deposition, in accordance with some embodiments. In some embodiments, OPL 1210 is formed over the semiconductor device. The OPL 1210 is so deposited that SASI remains exposed.

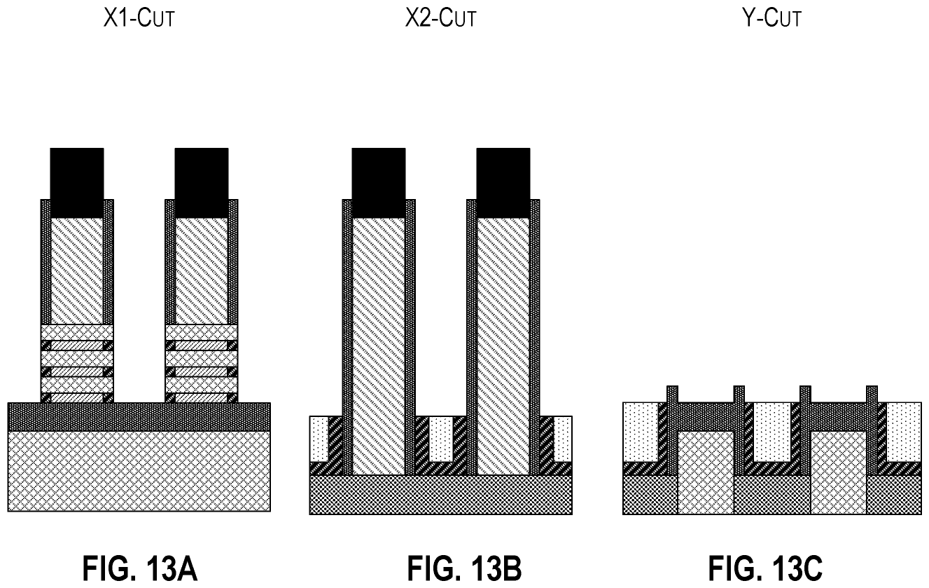

FIGS. 13A-13C illustrate a semiconductor device after etching the second spacer, in accordance with some embodiments. In some embodiments, portions of the second spacer that are not covered by the OPL are etched.

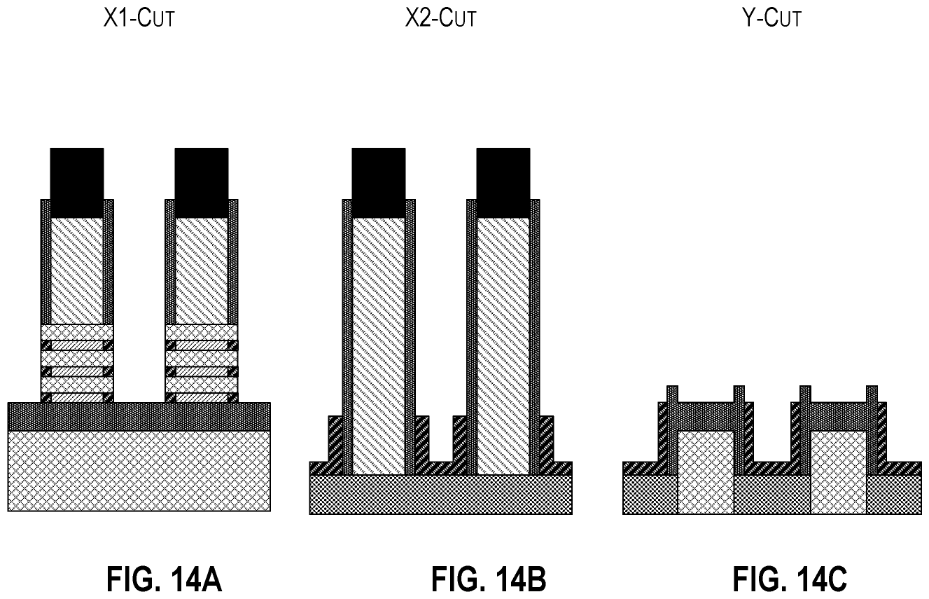

FIGS. 14A-14C illustrate a semiconductor device after stripping the OPL, in accordance with some embodiments. In some embodiments, the remaining OPL is stripped and SASI, the first spacer, and the second spacer are exposed.

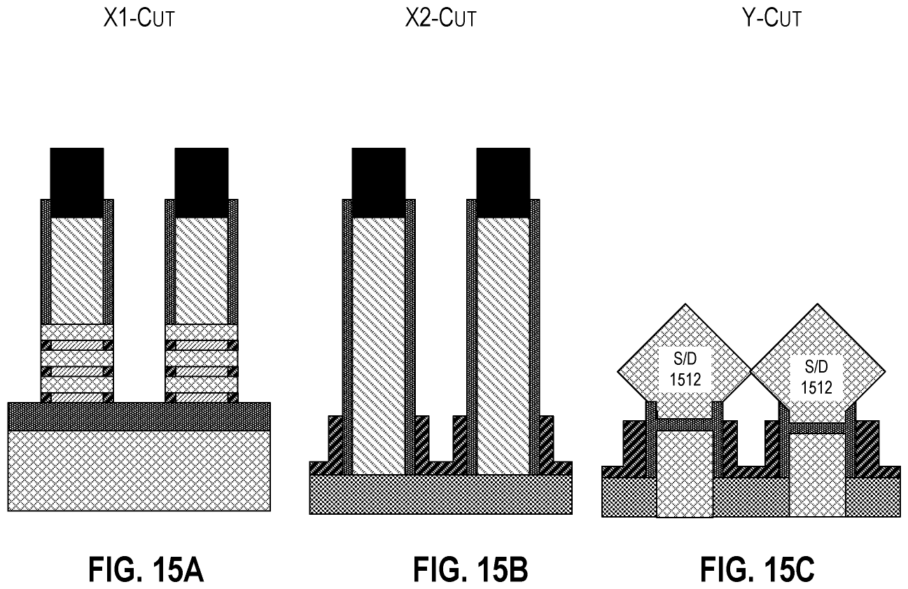

FIGS. 15A-15C illustrate a semiconductor device after the formation of the source/drain regions, in accordance with some embodiments. In some embodiments, the source/drain regions 1512 are formed. The source/drain regions 1512 can be epitaxially grown.

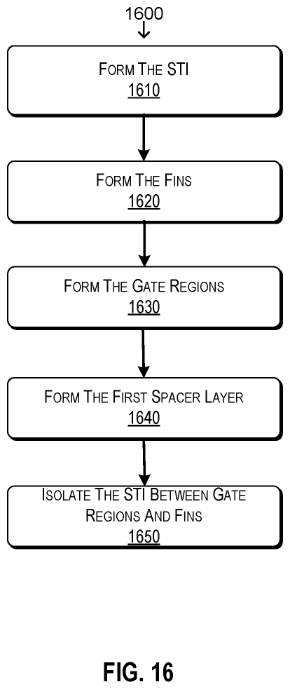

FIG. 16 illustrate a block diagram of a method 1600 for forming the semiconductor device, in accordance with some embodiments. As shown by block 1610, the STI is formed.

As shown by block 1620, the plurality of fins are formed.

As shown by block 1630, the plurality of gate regions are formed.

As shown by block 1640, the first spacer layer is formed.

As shown by block 1650, one the STI between the plurality of gate regions and the plurality of fins are isolated.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a shallow trench isolation (STI);
a plurality of fins over the STI, wherein each of the plurality of fins comprises at least a source/drain region;
a plurality of gate regions; and
a first spacer layer, wherein portions of the STI that are located between the plurality of fins and portions of the STI that are located between the plurality of gate regions are separated by the first spacer layer.

2. The semiconductor device of claim 1, wherein portions of sidewalls of the plurality of gate regions and portions of sidewalls of the plurality of fins are isolated by a second spacer layer.

3. The semiconductor device of claim 2, wherein the first spacer layer and the second spacer layer form a continuous layer.

4. The semiconductor device of claim 2, wherein the first spacer layer and the second spacer layer are made of a same material.

5. The semiconductor device of claim 2, wherein the first spacer layer and the second spacer layer are made of different materials.

6. The semiconductor device of claim 1, wherein the semiconductor device is a nanosheet field-effect transistor (FET).

7. The semiconductor device of claim 6, wherein the nanosheet FET includes nanosheets of alternating layers of silicon and silicon germanium.

8. A semiconductor device, comprising:
a shallow trench isolation (STI);
a plurality of fins over the STI, wherein each of the plurality of fins comprises at least a source/drain region;
a plurality of gate regions; and
a first spacer layer, wherein portions of sidewalls of the plurality of gate regions and portions of sidewalls of the plurality of fins are isolated by the first spacer layer.

9. The semiconductor device of claim 8, wherein portions of the STI between the plurality of fins and portions of the STI between the plurality of gate regions are isolated by a second spacer layer.

10. The semiconductor device of claim 9, wherein the first spacer layer and the second spacer layer form a continuous layer.

11. The semiconductor device of claim 9, wherein the first spacer layer and the second spacer layer are made of a same material.

12. The semiconductor device of claim 9, wherein the first spacer layer and the second spacer layer are made of different materials.

13. The semiconductor device of claim 8, wherein the semiconductor device is a nanosheet field-effect transistor (FET).

14. The semiconductor device of claim 13, wherein the nanosheet FET includes nanosheets of alternating layers of silicon and silicon germanium.

15. A method for forming a semiconductor device, the method comprising:
forming a shallow trench isolation (STI);
forming a plurality of fins over the STI, wherein forming each of the plurality of fins comprises forming at least a source/drain region;
forming a plurality of gate regions;
forming a first spacer layer; and
isolating portions of the STI that are located between the plurality of fins and portions of the STI that are located between the plurality of gate regions by the first spacer layer.

16. The method of claim 15, further comprising isolating portions of sidewalls of the plurality of gate regions and portions of sidewalls of the plurality of fins by a second spacer layer.

17. The method of claim 16, further comprising forming a continuous layer by connecting the first spacer layer and the second spacer layer.

18. The method of claim 16, wherein the first spacer layer and the second spacer layer are made of a same material.

19. The method of claim 16, wherein the first spacer layer and the second spacer layer are made of different materials.

20. The method of claim 15, further comprising forming nanosheets of alternating layers of silicon and silicon germanium.
